(19) United States
(12) Patent Application Publication
(10) Pub. No.: US 2025/0316465 A1
(43) Pub. Date: Oct. 9, 2025

(54) FLUORINATION CLEANING DEVICE FOR CLEANING LINER-TYPE PART SEMICONDUCTOR DRY ETCHING SYSTEM AND FLUORINATION CLEANING APPARATUS INCLUDING THE SAME

(71) Applicants: WONIK QNC Corporation, Gumi-si (KR); JESAGI HANKOOK LTD., Siheung-si (KR)

(72) Inventors: TAE IL BAEK, Gwacheon-si (KR); Tae Hoon PARK, Siheung-si (KR); Deog Jae OH, Hwasung-si (KR); Eun Young CHOI, Hwaseong-si (KR); Joo Hee JANG, Hwaseong-si (KR); Dong Ho SHIN, Seoul (KR); Min Seob JUNG, Seoul (KR)

(73) Assignees: WONIK QNC Corporation, Gumi-si (KR); JESAGI HANKOOK LTD., Siheung-si (KR)

(21) Appl. No.: 19/084,976

(22) Filed: Mar. 20, 2025

(30) Foreign Application Priority Data
Apr. 8, 2024 (KR) 10-2024-0047240

(51) Int. Cl. H01J 37/32; C23C 16/44; H01L 21/67

(52) U.S. Cl. CPC H01J 37/32862; C23C 16/4404; H01J 37/32449; H01J 37/32568; H01L 21/67069; H01J 2237/335

(57) ABSTRACT

Disclosed are a fluorination cleaning device for cleaning a liner-type part for a semiconductor dry etching system and a fluorination cleaning apparatus for forming yttrium oxyfluoride on an yttria-coated part including the same, which may easily form an yttrium oxyfluoride layer on an yttria-coated part using process gas under specific conditions. The fluorination cleaning device includes: a process chamber body; a process gas inlet provided on one side of the process chamber body and configured to introduce process gases; a process gas outlet provided on the other side of the process chamber body and configured to discharge the process gases; a heating member provided in the process chamber body; a plasma power electrode member composed of electrode members arranged in the process chamber body at a distance from each other in a radial direction; and a support plate provided at the bottom inside the process chamber body.

### BACKGROUND

### 1. Technical Field

The present disclosure relates to a fluorination cleaning device for cleaning a liner-type part for a semiconductor dry etching system and a fluorination cleaning apparatus for forming yttrium oxyfluoride on an yttria-coated part including the same. More specifically, the present disclosure relates to a fluorination cleaning device for cleaning a liner-type part for a semiconductor dry etching system and a fluorination cleaning apparatus for forming yttrium oxyfluoride on an yttria-coated part including the same, which may easily form an yttrium oxyfluoride (YOF) layer on an yttria (Y₂O₃)-coated liner-type part for a semiconductor etching system by plasma heat treatment using process gases, including CF₄ reactive gas, under specific treatment conditions.

### 2. Related Art

Among semiconductor manufacturing systems, a semiconductor dry etching system should be shut down for regular system inspection or parts replacement (maintenance), and then subjected to a back-up process to ensure normal operation of the semiconductor manufacturing system before restart of the system.

The back-up process for the semiconductor dry etching system is performed through several steps: an out-gassing step of removing water and the like from the system; a step of reducing contaminant particles in the system; an aging step of fluorinating the inside of the system; and a step of verifying sample quality (In Fab. Data) step using mass-produced wafers.

Thereamong, an aging process is performed to form a fluoride atmosphere capable of ensuring a normal etching rate in the semiconductor dry etching system. In this aging process, a certain level of etching gas is allowed to react with the surface of a plasma-resistant coating (Al₂O₃, Y₂O₃, YAG, etc.) provided in the system to form a fluoride layer having a composition containing F element on the surface to a thickness of several nm to several hundred nm.

If a fluorine atmosphere is not sufficiently formed in the semiconductor dry etching system, a problem may arise in that the time for repeating the aging process becomes longer, leading to a significant reduction in the normal etching process time, which may cause a decrease in the productivity of the semiconductor manufacturing system and an increase in the manufacturing cost.

As an example of a conventional method for forming a fluoride layer, a method is known in which a part to be fluorinated is placed in a vacuum chamber, and then a low-pressure vacuum plasma is generated using a fluorine-containing gas such as CF₄, SF₆, or NF₃, so that the surface is fluorinated by fluorine-containing radicals (“Fabrication, characterization, and fluorine-plasma exposure behavior of dense yttrium oxyfluoride ceramic”, T Tsunoura et al., Japanese Journal of Applied Physics 56, 06HC02 (2017), “Fluorination mechanisms of Al₂O₃ and Y₂O₃ surfaces irradiated by high-density CF₄/O₂ and SF₆/O₂ plasmas”, K Miwa et al, J Vac Sci Technol A 27(4), July/August 2009).

However, this method has disadvantages in that it requires the construction of a vacuum chamber and corresponding vacuum devices, which is disadvantageous for mass production and results in low economic feasibility, and in that, since it uses a low-pressure plasma process, the density of fluorine-containing radicals is low, and thus the fluorination rate is low, leading to reduced productivity.

As another example, a method is known in which a part to be fluorinated is immersed in a solution of HF, SF₄, CHF₃ or the like, and then the surface thereof is fluorinated by increasing the temperature to about 250° C. (“Preparation of Fluorinated-γ-Alumina”, E Kemnitz et al., “Efficient Preparations of Fluorine Compounds”, Edited by H W Roesky, 2013, 442).

However, this method has a disadvantage in terms of process safety because it uses a hazardous solution during the handling and treatment processes.

In addition, as other examples, U.S. Pat. No. 8,206,829 and/or US Patent Application Publication No. 2017/0114440 is/are known. These patent documents disclose a method of coating the surface of a part with a powder material such as AlF₃, YF₃, AlOF, or YOF by a method such as plasma spraying.

However, there is a disadvantage in that, since the raw material price of AlF₃ or YF₃, which is a coating raw material used for a ceramic protective coating such as alumina (Al₂O₃) or yttria (Y₂O₃), is very high and the supply of the raw material is not smooth as the raw material suppliers are limited, economic feasibility is low. In addition, when the fluoride coating is formed by the above method, there is a problem in that a relatively large amount of plasma particles are generated, which reduces the reliability of the fluoride coating. To overcome these problems, research and development are required.

### PATENT DOCUMENTS

Korean Patent No. 10-1309716 (published on Sep. 17, 2013)

U.S. Pat. No. 8,206,829 (registered on Jun. 26, 2012)

US Patent Application Publication No. 2017/0114440 (published on Apr. 27, 2017)

### SUMMARY

Therefore, the present disclosure has been made in order to solve the above-described problems occurring in the prior art, and an object of the present disclosure is to provide a fluorination cleaning device for cleaning a liner-type part for a semiconductor dry etching system and a fluorination cleaning apparatus for forming yttrium oxyfluoride on an yttria-coated part including the same, which may easily form the same yttrium oxyfluoride (YOF) layer having the same composition as that of a coating layer, which is formed in a normal etching process, on an yttria (Y₂O₃)-coated liner-type part for a semiconductor etching system by plasma heat treatment using process gases, including CF₄ reactive gas, under specific treatment conditions.

Objects to be achieved by the present disclosure are not limited to the objects mentioned above, and other objects not mentioned above may be clearly understood by those skilled in the art from the following description.

In accordance to one aspect of the present disclosure for achieving the objects and other features of the present disclosure, there is provided a fluorination cleaning device for cleaning a liner-type part having an yttria (Y₂O₃) coating layer for a semiconductor dry etching system, including: a process chamber body; a process gas inlet provided on one side of the process chamber body and configured to introduce process gases; a process gas outlet provided on the other side of the process chamber body and configured to discharge the process gases; a heating member provided in the process chamber body; a plasma power electrode member composed of electrode members arranged in the process chamber body at a distance from each other in a radial direction; and a support plate member provided at the bottom inside the process chamber body.

According to one aspect of the present disclosure for achieving the objects and other features of the present disclosure, there is provided that the heating member is provided along an inner wall of the process chamber body, and the plasma power electrode member comprises a first plasma power electrode member provided in the process chamber body concentrically around a center of the process chamber body, and a second plasma power electrode member provided outside the first power electrode at a distance therefrom.

According to one aspect of the present disclosure for achieving the objects and other features of the present disclosure, there is further comprised, at a process gas inlet side, a diffusion member that allows the process gases introduced through the process gas inlet to diffuse.

According to one aspect of the present disclosure for achieving the objects and other features of the present disclosure, the process chamber body is configured such that a lower portion forming a bottom of the process chamber body is separated from an upper portion, and the fluorination cleaning device further comprises an up-and-down driving unit that drives the lower portion to be movable up and down.

According to one aspect of the present disclosure for achieving the objects and other features of the present disclosure, there is further comprised a rotational driving unit that rotatably drives the support plate member.

In accordance to another aspect of the present disclosure, there is provided a fluorination cleaning apparatus for cleaning a liner-type part having an yttria (Y₂O₃) coating layer for a semiconductor dry etching system, including: a plasma-heat treatment unit which is the fluorination cleaning device for cleaning a liner-type part according to said one aspect; a process gas supply unit configured to supply a discharge gas, a non-fluorine reactive gas, and a reactive gas, which are process gases, to the plasma-heat treatment unit; and a cleaning control unit configured to control the plasma heat treatment environment of the plasma-heat treatment unit and the flow rates of the process gases that are supplied from the process gas supply unit.

The fluorination cleaning device for cleaning a liner-type part for a semiconductor dry etching system and the fluorination cleaning apparatus for forming yttrium oxyfluoride on an yttria-coated part including the same according to the present disclosure have the following effects.

First, the present disclosure has the effect of providing a fluorination cleaning device exclusively for a liner-type part, which may easily perform fluorination cleaning of the liner-type part.

Second, the present disclosure has the effect of increasing the coating life of a liner-type part, thereby increasing economic efficiency.

Third, the present disclosure has the effect of shortening the time of aging for ensuring a normal etching rate in a seasoning process for a semiconductor dry etching system, thereby improving productivity.

Fourth, the present disclosure has the effect of imparting high density and high strength to an yttria (Y₂O₃)-coated liner-type part and maximally reducing the generation of contaminant particles, thus ensuring a normal etching rate.

Fifth, the present disclosure has the effect of uniformly

forming a YOF coating layer having the same composition as a coating layer, which is formed in a normal etching process, on a large-area liner-type part, and forming YOF coating layers having various compositions.

### BRIEF DESCRIPTION OF THE DRAWINGS

FIG. 1 is a block diagram schematically showing the configuration of a fluorination cleaning apparatus for forming yttrium oxyfluoride including a fluorination cleaning device for cleaning a liner-type part for a semiconductor dry etching system according to the present disclosure.

FIG. 2 is a cross-sectional perspective view showing a fluorination cleaning device for cleaning a liner-type part for a semiconductor dry etching system according to the present disclosure.

FIG. 3 is an exploded perspective view showing a fluorination cleaning device for cleaning a liner-type part for a semiconductor dry etching system according to the present disclosure.

FIG. 4 is a perspective view showing a portion of a fluorination cleaning device for cleaning a liner-type part for a semiconductor dry etching system according to the present disclosure.

FIG. 5 schematically shows a plasma generation mode of a first embodiment, which is executed by a cleaning control unit included in a fluorination cleaning apparatus for forming yttrium oxyfluoride including a fluorination cleaning device for cleaning a liner-type part for a semiconductor dry etching system according to the present disclosure.

FIG. 6 schematically shows a plasma generation mode of a second embodiment, which is executed by a cleaning control unit included in a fluorination cleaning apparatus for forming yttrium oxyfluoride including a fluorination cleaning device for cleaning a liner-type part for a semiconductor dry etching system according to the present disclosure.

FIG. 7 schematically shows a plasma generation mode of a third embodiment, which is executed by a cleaning control unit included in a fluorination cleaning apparatus for forming yttrium oxyfluoride including a fluorination cleaning device for cleaning a liner-type part for a semiconductor dry etching system according to the present disclosure.

FIG. 8 schematically shows a plasma generation mode of a fourth embodiment, which is executed by a cleaning control unit included in a fluorination cleaning apparatus for forming yttrium oxyfluoride including a fluorination cleaning device for cleaning a liner-type part for a semiconductor dry etching system according to the present disclosure.

FIG. 9 is an electron micrograph of a coating layer of an yttria-coated part after performing fluorination cleaning using a fluorination cleaning method for forming yttrium oxyfluoride on an yttria-coated part for a semiconductor dry etching device according to the present disclosure.

FIG. 10 is a table showing the results of comparing the surface microstructure depending on power in RIE mode and the F content depending on power and reaction layer depth.

FIG. 11 is a table showing the results of comparing the surface microstructure depending on the flow rate ratio between O₂ and CF₄ gases and the C content and F content depending on the flow rate ratio between O₂ and CF₄ gases and depth.

FIG. 12 is a table showing the results of comparing the surface/cross-section microstructure depending on the reaction temperature and the F content according to reaction temperature and depth.

FIG. 13 is a table showing the results of XRD analysis depending on the reaction temperature.

FIG. 14 is a table showing the results of comparing the surface microstructure depending on low-frequency (LF) power in PE mode and the F content depending on power and depth.

FIG. 15 is a table showing the results of comparing the surface microstructure depending on the reaction time and the C content and F content depending on reaction time and depth.

FIG. 16 is a table showing the results of comparing microstructure and XPS depth profiling depending on chamber working pressure (treatment pressure).

FIG. 17 is a table showing the results of comparing the surface microstructure depending on the flow rate ratio between O₂ and CF₄ gases and the C content and F content depending on the flow rate ratio between O₂ and CF₄ gases and depth.

FIG. 18 is a table comparing the surface microstructure and the F content depending on the distance from the electrode, LF (low frequency) plasma power, and reaction time in floating mode.

FIG. 19 is a table showing the results of comparing the surface microstructure and the F content depending on power and the number of cycles.

FIG. 20 is a table showing the results of performing fluorination cleaning on Y₂O₃ using the process parameters of a fourth embodiment.

### DETAILED DESCRIPTION

Specific embodiments according to the present disclosure will be described below with reference to the accompanying drawings. However, this is not intended to limit the invention to any particular embodiment, and is to be understood to include all modifications, equivalents, and substitutions that fall within the idea and technical scope of the invention.

Throughout the specification, parts having like construction and operation are designated by the same reference signs. In addition, the accompanying drawings of the present disclosure are for the convenience of illustration only, and shapes and relative dimensions thereof may be exaggerated or omitted.

In describing embodiments in detail, redundant descriptions or descriptions of techniques that are obvious in the field are omitted. In addition, whenever any part is the to “include” other components in the following description, it is intended to include components in addition to those listed, unless the contrary is specifically indicated.

In addition, terms such as “part,” “section,” “module,” and the like used herein mean a unit that performs at least one function or operation, which may be implemented in hardware, software, or a combination of hardware and software. Also, when one part is the to be electrically connected to another part, this includes direct connections as well as connections with other configurations in between.

Terms containing ordinal numbers, such as first, second, and the like, may be used to describe various components, but the components are not limited by such terms. These terms are used only to distinguish one component from another. For example, a second component may be named as a first component, and similarly, a first component may be named as a second component, without departing from the scope of the present disclosure.

Hereinafter, the fluorination cleaning device for cleaning a liner-type part for a semiconductor dry etching system and the fluorination cleaning apparatus for forming yttrium oxyfluoride on an yttria-coated part including the same according to preferred embodiments of the present disclosure will be described in detail with reference to the accompanying drawings.

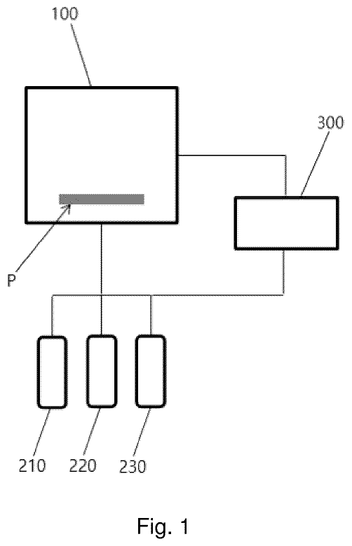

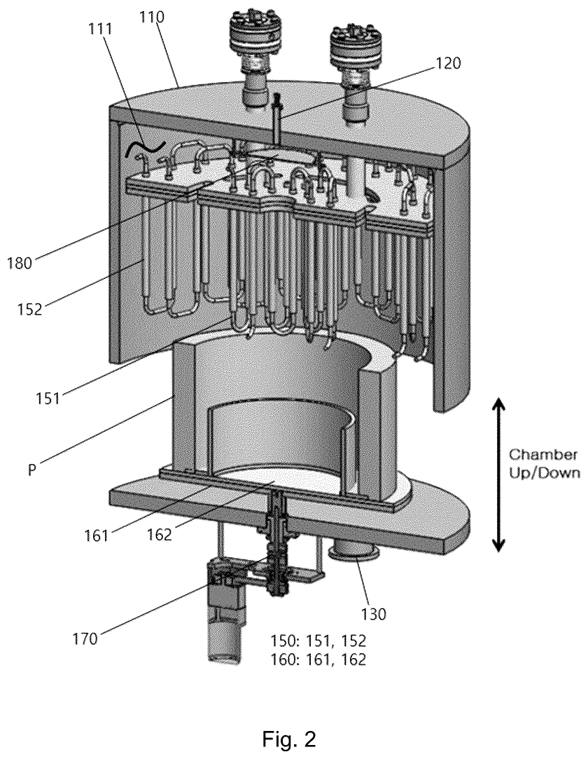

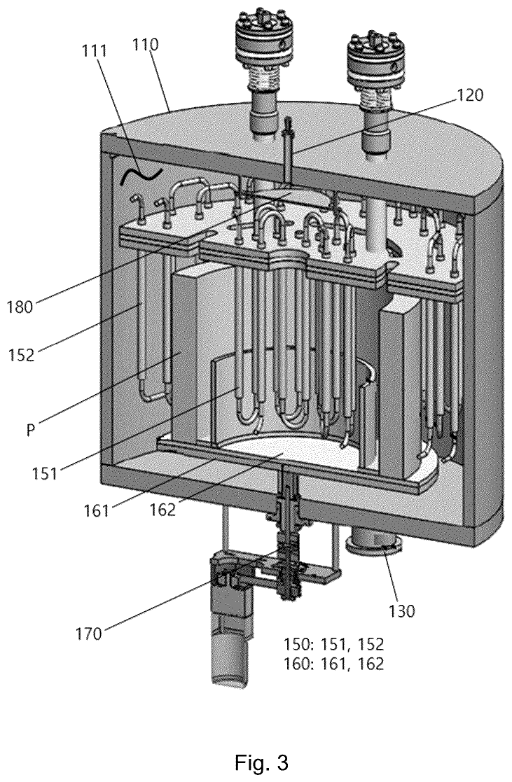

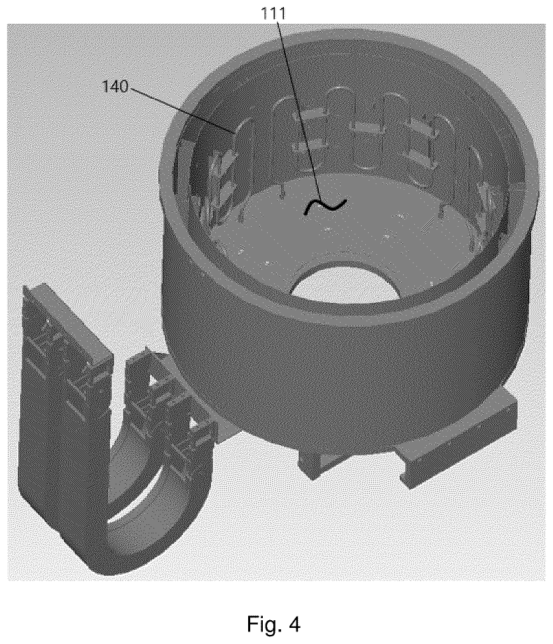

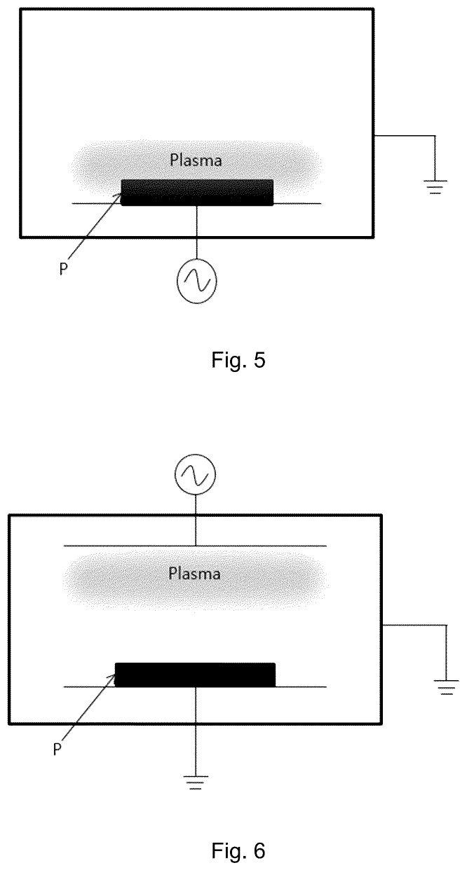

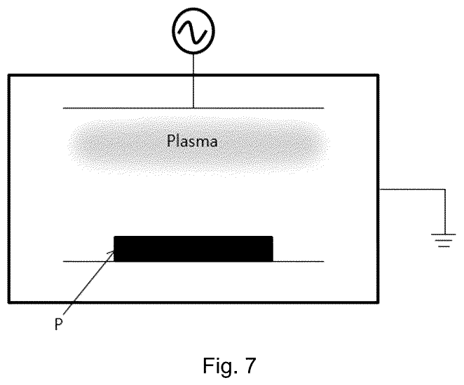

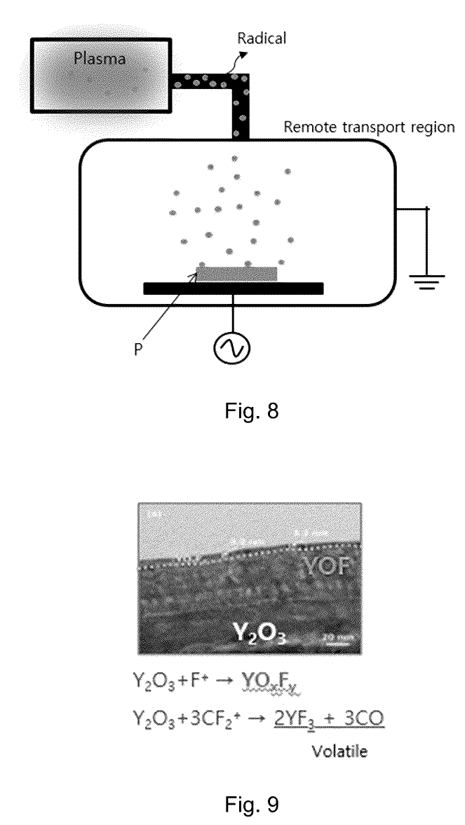

FIG. 1 is a block diagram schematically showing the configuration of a fluorination cleaning apparatus for forming yttrium oxyfluoride including a fluorination cleaning device for cleaning a liner-type part for a semiconductor dry etching system according to the present disclosure, FIG. 2 is a cross-sectional perspective view showing a fluorination cleaning device for cleaning a liner-type part for a semiconductor dry etching system according to the present disclosure, and FIG. 3 is an exploded perspective view showing a fluorination cleaning device for cleaning a liner-type part for a semiconductor dry etching system according to the present disclosure. FIG. 4 is a perspective view showing a portion of a fluorination cleaning device for cleaning a liner-type part for a semiconductor dry etching system according to the present disclosure, FIG. 5 schematically shows a plasma generation mode of a first embodiment, which is executed by a cleaning control unit included in a fluorination cleaning apparatus for forming yttrium oxyfluoride including a fluorination cleaning device for cleaning a liner-type part for a semiconductor dry etching system according to the present disclosure, and FIG. 6 schematically shows a plasma generation mode of a second embodiment, which is executed by a cleaning control unit included in a fluorination cleaning apparatus for forming yttrium oxyfluoride including a fluorination cleaning device for cleaning a liner-type part for a semiconductor dry etching system according to the present disclosure. FIG. 7 schematically shows a plasma generation mode of a third embodiment, which is executed by a cleaning control unit included in a fluorination cleaning apparatus for forming yttrium oxyfluoride including a fluorination cleaning device for cleaning a liner-type part for a semiconductor dry etching system according to the present disclosure, FIG. 8 schematically shows a plasma generation mode of a fourth embodiment, which is executed by a cleaning control unit included in a fluorination cleaning apparatus for forming yttrium oxyfluoride including a fluorination cleaning device for cleaning a liner-type part for a semiconductor dry etching system according to the present disclosure, and FIG. 9 is an electron micrograph of a coating layer of an yttria-coated part after performing fluorination cleaning using a fluorination cleaning method for forming yttrium oxyfluoride on an yttria coating part for a semiconductor dry etching device according to the present disclosure.

The fluorination cleaning apparatus for forming yttrium oxyfluoride including the fluorination cleaning device for cleaning a liner-type part for a semiconductor dry etching system according to the present disclosure is a fluorination cleaning apparatus for cleaning a part (such as a liner) having a plasma-resistant yttria (Y₂O₃) coating layer for a semiconductor dry etching system, and as shown in FIGS. 1 to 9, it generally includes a plasma-heat treatment unit 100, a process gas supply unit 210, 220 and 230, and a cleaning control unit 300.

Specifically, the fluorination cleaning apparatus for forming yttrium oxyfluoride including the fluorination cleaning device for cleaning a liner-type part for a semiconductor dry etching system according to the present disclosure is a fluorination cleaning apparatus for cleaning a part (such as a liner) having a plasma-resistant yttria (Y₂O₃) coating layer for a semiconductor dry etching system, and as shown in FIGS. 1 to 9, it generally includes: a plasma-heat treatment unit 100 configured to perform plasma heat treatment on a part (P) having a plasma-resistant yttria (Y₂O₃) coating layer; a process gas supply unit 210, 220 and 230 configured to supply a discharge gas, a non-fluorine reactive gas, and a reactive gas, which are process gases, to the plasma-heat treatment unit 100; and a cleaning control unit 300 configured to control the plasma heat treatment environment of the plasma-heat treatment unit 100 and the introduction of the process gases that are supplied from the process gas supply unit 210, 220 and 230.

The plasma-heat treatment unit 100 is a fluorination cleaning device for cleaning a liner-type part, and includes: a process chamber body 110 having a treatment space 111 therein; a process gas inlet 120 provided on one side (upper side in the figure) of the process chamber body 110 and configured to introduce process gases into the treatment space 111; a process gas outlet 130 provided on the other side (lower side in the figure) of the process chamber body 110 and configured to discharge the process gases; a heating member 140 provided in the process chamber body 110; a plasma power electrode member 150 composed of electrodes arranged in the process chamber body at a distance from each other in a radial direction; and a support plate member 160 provided at the bottom inside the process chamber body.

The process chamber body 110 is formed in a cylindrical shape, has, on one side thereof, an opening/closing portion (not shown) that opens/closes to load the yttria-coated part, and is configured so that the inside thereof is kept airtight when closed by the opening/closing portion.

In addition, in another embodiment, the process chamber body 110 may be configured such that the lower portion forming the bottom is able to move up and down by an up-and-down driving unit (not shown), so that the yttria-coated part is loaded on the support plate member 160 in a state in which the lower portion is moved down, and then the lower portion is moved up to close the treatment space of the process chamber body 110.

The process gas inlet 120 may be provided at the central portion of the upper side of the process chamber body 110, and the process gas outlet 130 may be provided at the lower side of the process chamber body 110.

The heating member 140 is composed of a ceramic heater provided along the inner wall of the process chamber body 110.

In the figure, the heating member 141 may be configured such that U-shaped heaters are provided continuously in a zigzag pattern along the inner wall of the process chamber body 110. The heating member 141 may be composed of a spiral ceramic heater, a coil ceramic heater, or a plate-shaped ceramic heater.

The plasma power electrode member 150 is composed of electrodes provided in the process chamber body 110 with a gap therebetween in a radial direction, and a cylindrical yttria-coated part, such as a liner, is positioned in the gap.

Specifically, the plasma power electrode member 150 includes a first plasma power electrode member 151 provided in the process chamber body 110 concentrically around the center of the process chamber body 110 (i.e., provided relatively close to the center), and a second plasma power electrode member 152 provided outside the first power electrode 151 at a distance therefrom.

The first plasma power electrode member 151 and the second plasma power electrode member 152 are arranged in a circular shape when viewed from the top, and for example, U-shaped cylindrical electrode members may be provided continuously.

The support plate member 160 is a component which is provided at the bottom the process chamber body 110 and on which the yttria-coated part is placed.

The support plate 160 may include a base plate 161 and a ceramic plate 162 provided on the upper surface of the base plate 161.

Here, the support plate member 160 of the plasma-heat treatment unit 100 according to a second embodiment may be configured to be rotatably driven by a rotational driving unit 170 at the bottom of the process chamber body 110.

Meanwhile, the plasma-heat treatment unit 100 may further include, at the process gas inlet 120 side in the treatment space 111 of the process chamber body 110, a diffusion member 180 that allows the process gases introduced through the process gas inlet 120 to diffuse.

The diffusion member 180 may be composed of a diffusion plate provided at a certain distance from the injection end of the process gas inlet 120, wherein the diffusion plate may be formed in a plate shape as shown in the figure, and may be composed of a dome-shaped plate or a triangular plate.

The plasma-heat treatment unit 100 configured as described above may be applied to a part formed in a tubular shape, such as a liner.

The process gas supply unit 210, 220 and 230 is configured to supply discharge gas, non-fluorine reactive gas, and reactive gas, respectively, to the plasma-heat treatment unit 100.

The process gas supply unit 210, 220 and 230 is configured to introduce the discharge gas Ar, the non-fluorine reactive gas O₂, and CF₄ reactive gas, which are process gases, into the treatment space 111 at flow rates controlled by the cleaning control unit 300.

In addition to Ar gas, inert gas such as He, Ne, Ar, Kr, or Xe may be used as the discharge gas. Also, in addition to oxygen (O₂) gas, nitrogen (N₂), air, etc. may be used as the non-fluorine reactive gas. Also, in addition to the fluorine-containing reactive gas CF₄, a carbon fluoride gas such as C₂F₆ or C₄F₈, or nitrogen trifluoride (NF₃) gas, etc. may be used. However, in the present disclosure, preferably, argon (Ar) gas is used as the discharge gas, oxygen (O₂) is used as the non-fluorine reactive gas, and carbon tetrafluoride (CF₄) is used as the fluorine-containing reactive gas.

The cleaning control unit 300 is a unit configured to control

the plasma heat treatment environment of the plasma-heat treatment unit 100 and the introduction of process gases supplied from the process gas supply unit 210, 220 and 230, and controls a combination of a plurality of process parameters among process parameters, including process gas introduction amounts, plasma generation power, treatment time, heat treatment temperature, treatment space pressure, and the number of treatment cycles to perform cleaning while forming a yttrium oxyfluoride (YOF) layer of a predetermined thickness on the yttria-coated part.

The cleaning control unit 300 may employ various methods which are classified, according to the type of plasma source used in the known plasma etching process, into a reactive ion etching (RIE) method, a plasma etching (PE) method, and a remote plasma source (RPS) method, and may employ a floating plasma source method for forming a floating potential.

Specifically, in a first embodiment, the cleaning control

unit 300 may be configured to control plasma generation power, heat treatment temperature (i.e., part temperature), treatment space pressure, process gas flow rates, and treatment time as the process parameters.

Preferably, the cleaning control unit 300 of the first embodiment controls process parameters in RIE mode as shown in FIG. 5, wherein the process parameters to be controlled are a plasma generation power (RF/LF plasma power) of 100 W to 1,200 W (preferably 100 W to 300 W), a heat treatment temperature (i.e., part temperature) of room temperature to 600° C. (preferably 250° C. to 300° C.), a treatment space pressure of 90 mTorr to 110 mTorr (preferably 100 mTorr), a flow rate ratio between non-fluorine reactive gas and fluorine-containing reactive gas CF₄ of 0:100, and a treatment time of 15 to 180 minutes.

The cleaning control mode of the first embodiment is a mode having high reactivity and capable of controlling the heat treatment temperature, and performs cleaning to form yttrium oxyfluoride (YOF) on the coating layer of the part.

In a second embodiment, the cleaning control unit 300 is configured to control LF plasma generation power, heat treatment temperature (i.e., part temperature), treatment space pressure, process gas flow rates, and treatment time as the process parameters.

Preferably, the cleaning control unit 300 of the second embodiment controls process parameters in PE mode as shown in FIG. 6, wherein the process parameters to be controlled are an LF plasma generation power of 300 W to 1,200 W, a heat treatment temperature (i.e., part temperature) of room temperature to 600° C. (preferably 250° C. to 300° C.), a treatment space pressure of 90 mTorr to 550 mTorr (preferably 100 mTorr to 500 mTorr), a flow rate ratio between discharge gas (Ar), non-fluorine reactive gas (O₂) and fluorine-containing reactive gas (CF₄) of 0:(10 to 90):(10 to 90) or 50:(10 to 50):(18 to 45), and a treatment time of 15 to 60 minutes.

The cleaning control mode of the second embodiment may secure large-area uniformity in the formation of yttrium oxyfluoride (YOF) depending on the arrangement of the plasma generating electrodes.

In a third embodiment, the cleaning control unit 300 may be configured to control LF plasma generation power, the flow rate ratio between non-fluorine reactive gas (O₂) and fluorine-containing reactive gas (CF₄), and treatment time as the process parameters, and may further control the distance between the plasma and the part (the distance between the plasma generating electrode and the target part) and/or the number of treatment cycles.

Preferably, the cleaning control unit 300 of the third embodiment controls process parameters in floating mode as shown in FIG. 7, wherein the process parameters to be controlled may be an LF plasma generation power of 1 kW to 7 kW, a ratio between non-fluorine reactive gas (O₂) and fluorine-containing reactive gas (CF₄) of 90:10 or 0:100, and a treatment time of 10 to 70 minutes (preferably, 10 to 60 minutes). In the case where the distance between the plasma and the part and/or the number of treatment cycles are further included, the distance between the plasma and the part is preferably 30 mm to 50 mm (preferably 40 mm), and the number of treatment cycles is 1 to 3.

The cleaning control mode of the third embodiment may reduce or prevent an arcing phenomenon that occurs when an overcurrent flows to one portion for some reason and the voltage further increases, and may secure large-area uniformity in the formation of yttrium oxyfluoride (YOF) depending on the arrangement of the plasma generating electrodes.

The third embodiment described above uses a floating plasma source method of forming a floating potential. When the part is placed in plasma, the surrounding electrons and ions collide with the sample, and since the electron speed per unit time is faster than the ion speed, the part has a minus (−) potential, and at some point, the number of electrons entering and the number of positive ions entering reach equilibrium, and the current becomes 0. The potential at this time is called the floating potential.

In a fourth embodiment, the cleaning control unit 300 is configured to control microwave power for remote plasma generation, bias plasma power, the flow rate ratio between non-fluorine reactive gas (O₂) and fluorine-containing reactive gas (CF₄), and treatment time as the process parameters.

Preferably, the cleaning control unit 300) of the fourth embodiment controls process parameters in plasma mode as shown in FIG. 8, and the process parameters to be controlled thereby are preferably a microwave power for remote plasma generation of 1 kW to 2 kW, a bias plasma power of 500 W to 1,000 W (2 MHz plasma), a flow rate ratio between non-fluorine reactive gas (O₂) and fluorine-containing reactive gas (CF₄) of 10:1, and a treatment time of 15 minutes.

The cleaning control mode of the fourth embodiment is a method of performing cleaning in such a way that the interaction between plasma and the part occurs at a location remote from the plasma, and the cleaning control method of the fourth embodiment may form yttrium oxyfluoride (YOF) by a surface reaction with F radicals without direct influence of the plasma.

Meanwhile, the inventor of the present disclosure conducted experiments on cleaning control performed by the fluorination cleaning apparatus for forming yttrium oxyfluoride including the fluorination cleaning device for cleaning a liner-type part for a semiconductor dry etching system according to the present disclosure. The experimental results will be described below.

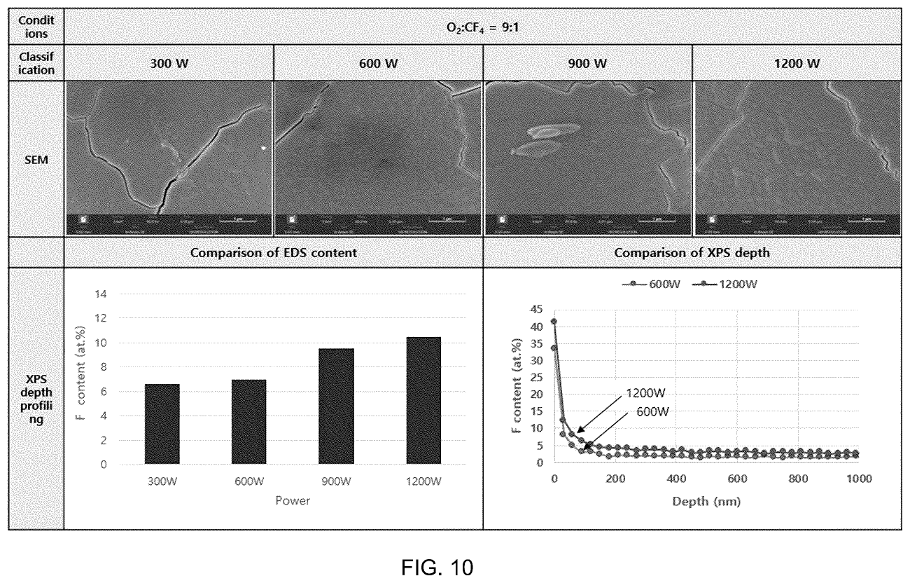

First, the experimental results obtained through fluorination cleaning control performed using the process parameters of the first embodiment will be described with reference to FIGS. 10 to 13.

FIG. 10 is a table showing the results of comparing the surface microstructure and the F content depending on power and reaction layer depth, and as shown therein, it was confirmed that, as the power increased, the F content increased.

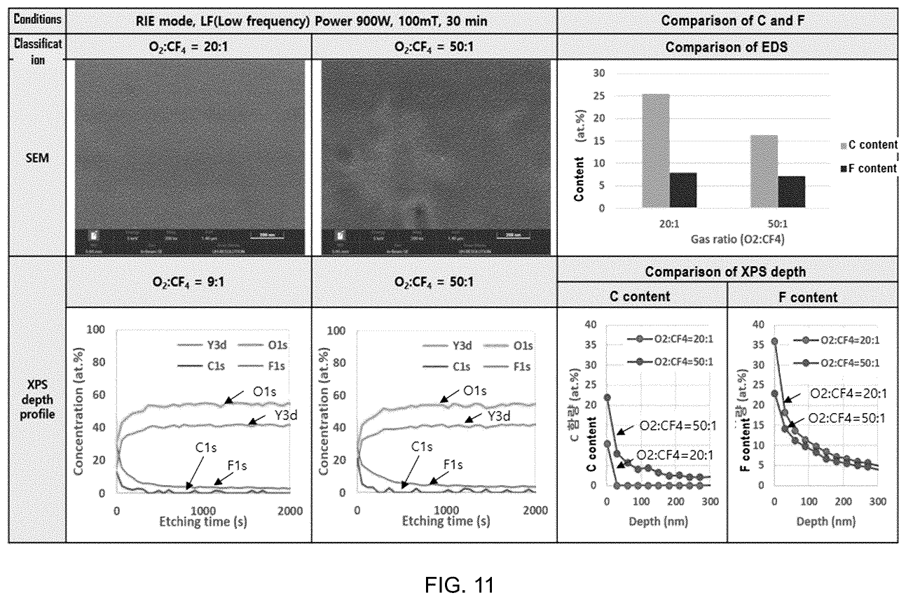

FIG. 11 is a table showing the results of comparing the surface microstructure depending on the gas flow ratio between O₂ and CF₄ and the C content and F content depending on the gas flow ratio between O₂ and CF₄ and depth. FIG. 11 is a table showing the results of comparing EDS and XPS depth profiling depending on the flow rate ratio between O₂ and CF₄ gases. As shown therein, as a result of EDS and XPS depth profiling, it was confirmed that, as the oxygen flow rate increased, the C content decreased, the F content increased, and there was an appropriate O₂ flow rate for removing carbon, and that, as the O₂ flow rate increased to a certain level or more and the CF₄ flow rate decreased, fluorination decreased.

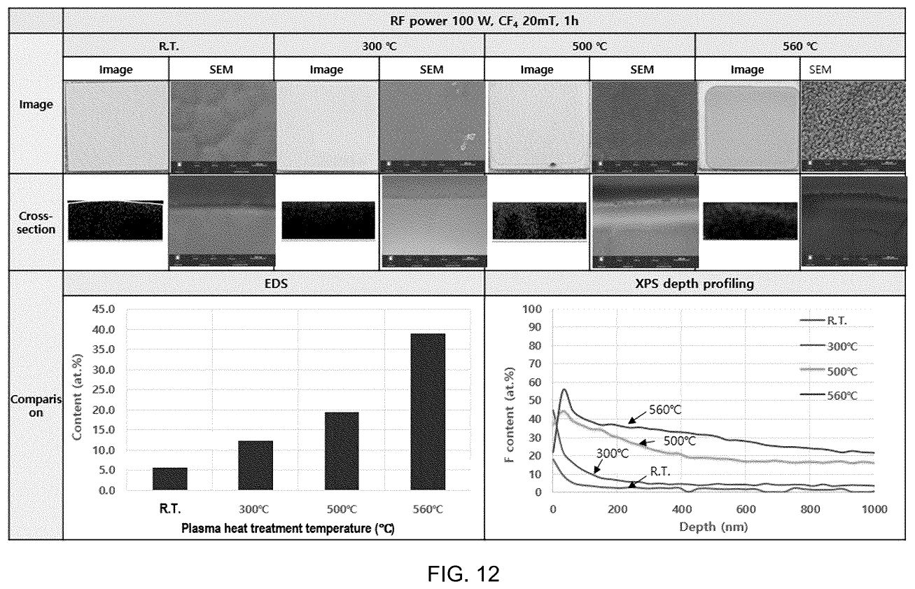

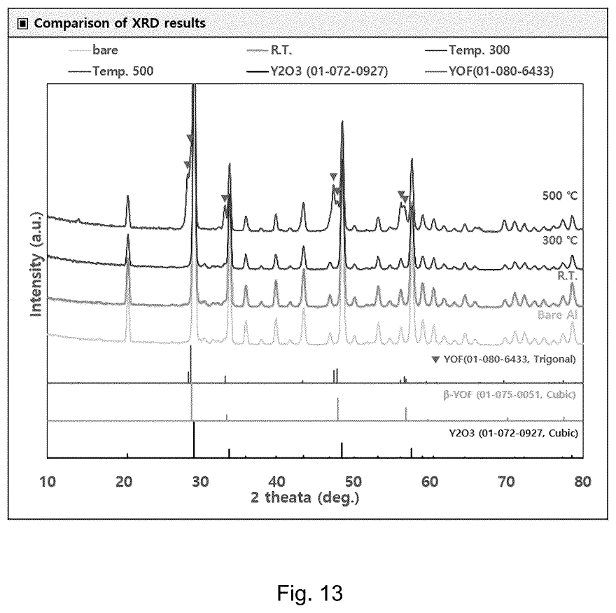

FIG. 12 is a table showing the results of evaluating fluorination cleaning depending on reaction temperature. As shown therein, it was confirmed that, as the reaction temperature increased, the F content increased, the fluorinated layer thickness increased, and the microstructure particle size increased. FIG. 13 is a table showing the results of XRD analysis depending on reaction temperature, and shows the results of analyzing the change in Y₂O₃ crystal structure depending on the reaction temperature. As shown therein, it was confirmed that there was no difference in the Y₂O₃ crystal structure after fluorination at room temperature (R.T) to 300° C., and the peak of the YOF crystal was observed after fluorination at 500° C. In the specimen after fluorination at 500° C., a YOF layer of about 500 nm was observed.

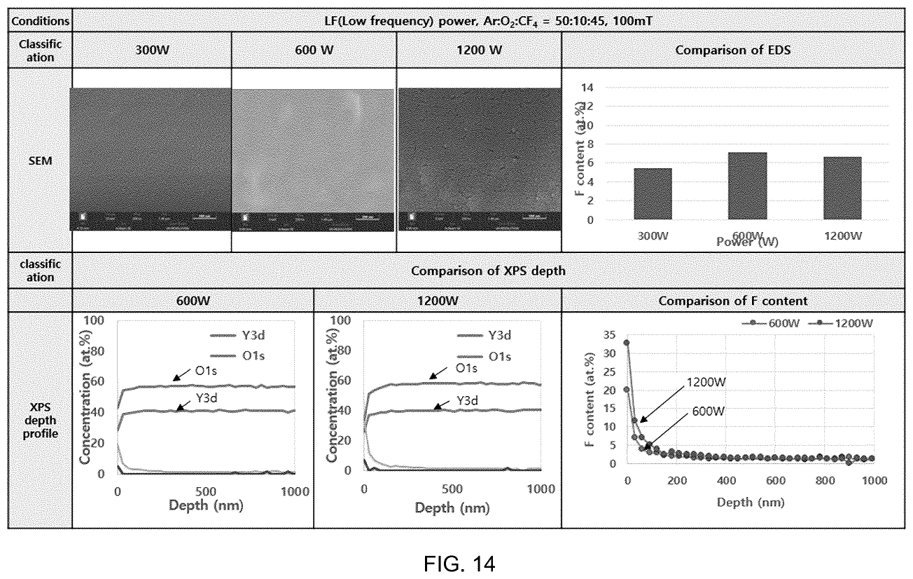

The experimental results obtained through fluorination cleaning control performed using the process parameters of the second embodiment will now be described with reference to FIGS. 14 to 17.

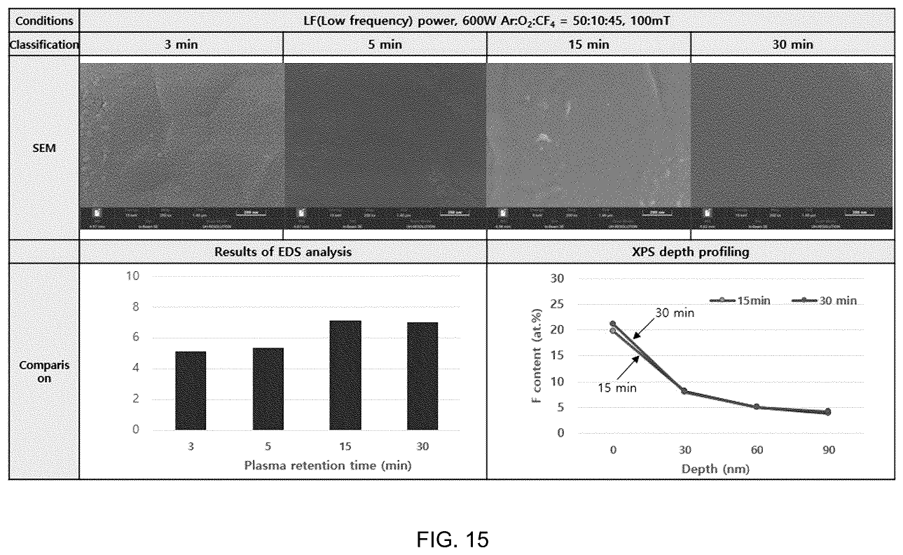

FIGS. 14 and 15 are tables showing the results of comparing the surface microstructure depending on power and reaction time in PE mode, and the F content and C content depending on reaction time and depth, respectively. As shown therein, as a result of EDS analysis, it was confirmed that there was no change in the F content even when the power was increased to 600 W or higher. However, in the results of XPS analysis, it was confirmed that the F content on the surface slightly increased as the power was increased.

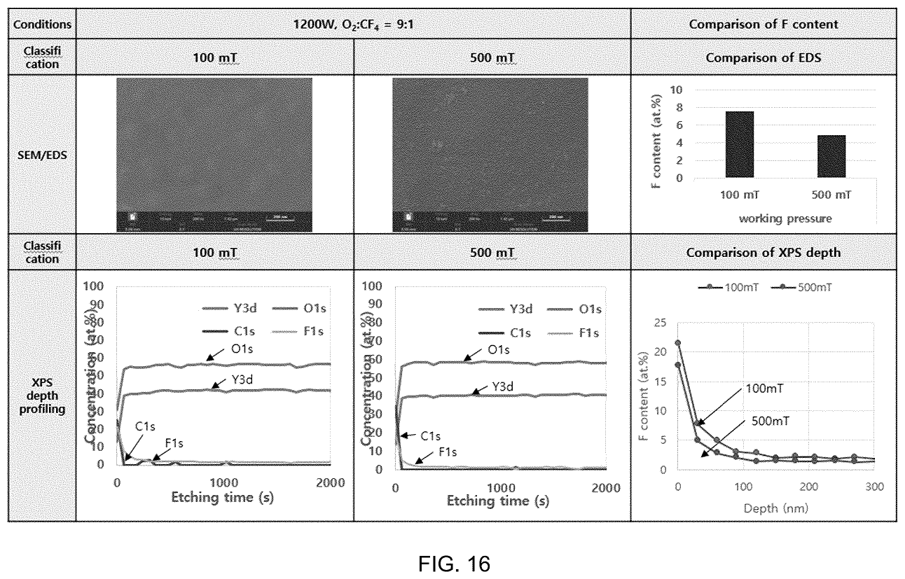

FIG. 16 is a table showing the results of comparing the surface microstructure depending on chamber working pressure (treatment pressure) and the F content depending on the working pressure and depth. As shown therein, as a result of comparing the F content depending on the chamber working pressure and depth, it was confirmed that the F content decreased as the chamber working pressure increased. This is believed to be because the scattering of ions increased as the chamber working pressure increased, resulting in a decrease in fluorination.

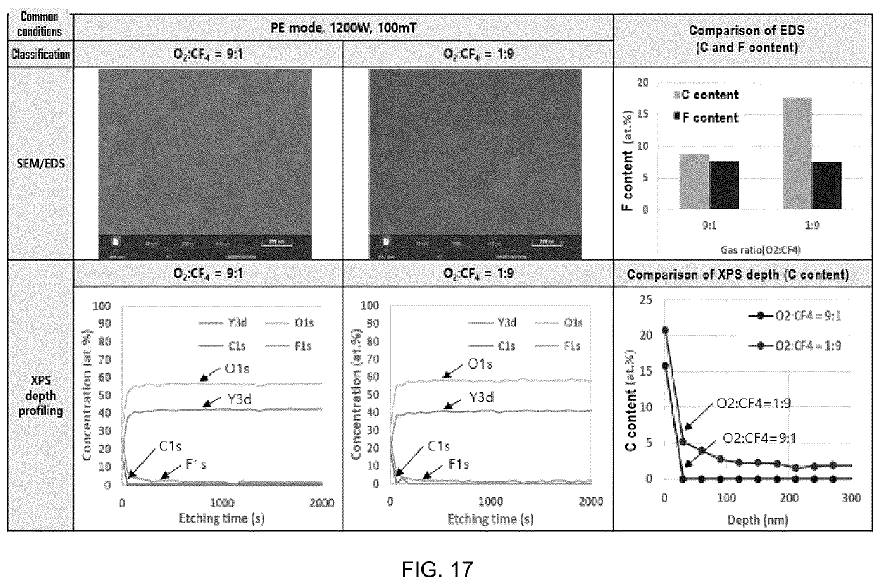

FIG. 17 is a table showing the results of comparing the surface microstructure depending on the flow rate ratio between O₂ and CF₄ gases and the F content and C content depending in the flow rate ratio between O₂ and CF₄ gases and depth. As shown therein, as a result of EDS and XPS depth profiling, it was confirmed that, as the O₂ flow rate increased, the C content decreased, but the F content did not change.

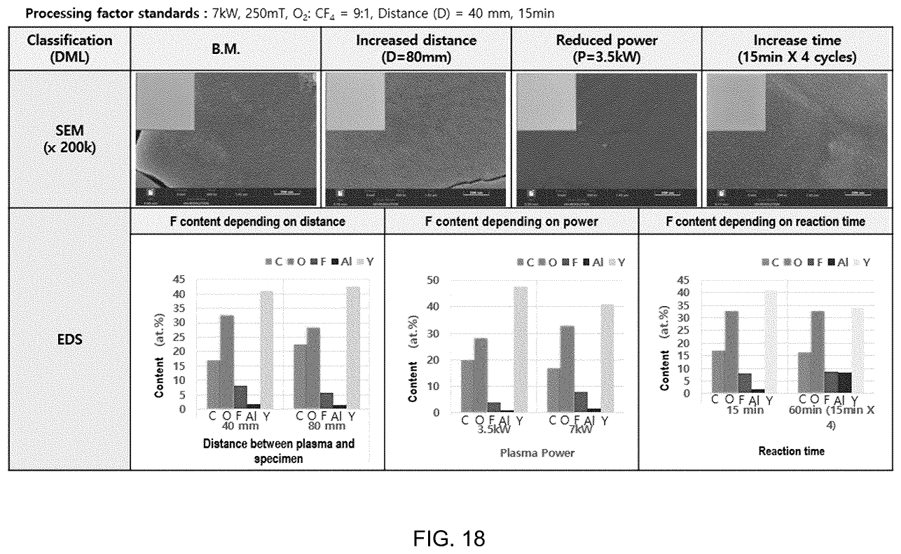

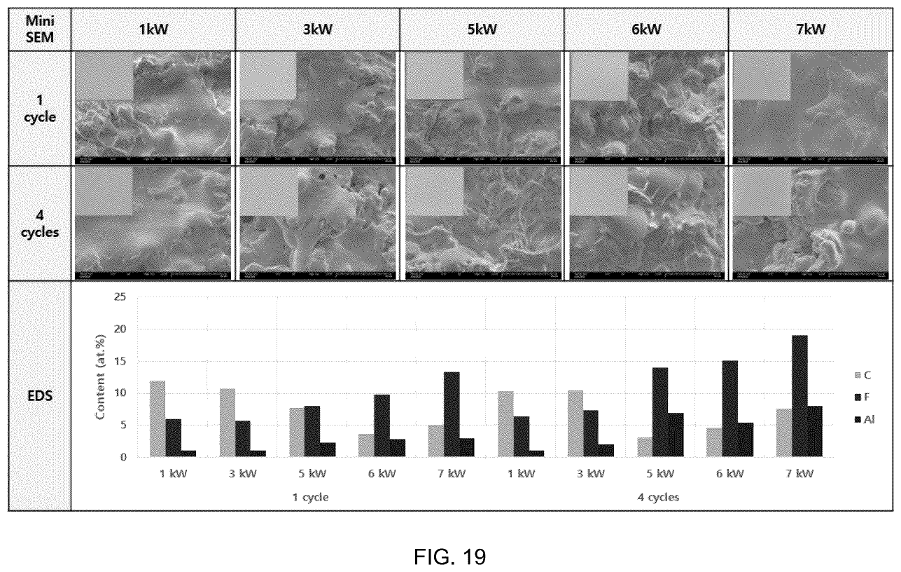

The experimental results obtained through fluorination cleaning control performed using the process parameters of the third embodiment will now be described with reference to FIGS. 18 and 19.

FIG. 18 is a table showing the results of analyzing the F content under the following process parameter conditions: power: 7 kW; 250 mT; O₂:CF₄=9:1; distance (D): 40 mm; and reaction time: 15 min. FIG. 19 is a table showing the results of evaluating fluorination cleaning depending on plasma power and reaction time. As shown therein, it was confirmed that, when the distance between the plasma generating electrode and the specimen increased beyond the upper limit of the process parameter, the F content decreased, and as the plasma power increased, the F content increased. In addition, it was confirmed that, when the reaction time exceeded 60 min, the F content slightly increased, but this increase was meaningless.

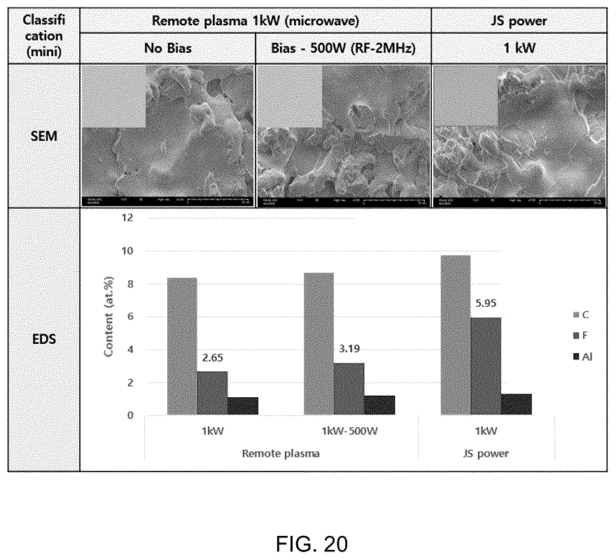

The experimental results obtained through fluorination cleaning control performed using the process parameters of the fourth embodiment will now be described with reference to FIG. 20.

FIG. 20 is a table showing the results of performing fluorination cleaning on Y₂O₃ using the process parameters of the fourth embodiment. As shown therein, it was confirmed that the F content was in the order of remote plasma<remote plasma-bias<LF plasma, indicating that LF plasma was most suitable for surface reaction.

According to the fluorination cleaning device for cleaning a liner-type part for a semiconductor dry etching system and the fluorination cleaning apparatus for forming yttrium oxyfluoride on an yttria-coated part including the same according to the present disclosure as described above, it is possible to provide a fluorination cleaning device exclusively for a liner-type part, which may easily perform fluorination cleaning of the liner-type part, and it is possible to increase the coating life of the liner-type part, thereby increasing economic efficiency.

In addition, according to the present disclosure, it is possible to shorten the time of aging for ensuring a normal etching rate in a seasoning process for a semiconductor dry etching system, thereby improving productivity. In addition, it is possible to impart high density and high strength to an yttria (Y₂O₃)-coated liner-type part and maximally reduce the generation of contaminant particles, thus ensuring a normal etching rate. In addition, it is possible to uniformly forms a YOF coating layer having the same composition as a coating layer, which is formed in a normal etching process, on a large-area liner-type part, and form YOF coating layers having various compositions.

While various embodiments have been described above, it will be understood to those skilled in the art that the embodiments described are by way of example only. Accordingly, the disclosure described herein should not be limited based on the described embodiments.

What is claimed is:

1. A fluorination cleaning device for cleaning a liner-type part having an yttria (Y₂O₃) coating layer for a semiconductor dry etching system, comprising:
a process chamber body;
a process gas inlet provided on one side of the process chamber body and configured to introduce process gases;
a process gas outlet provided on the other side of the process chamber body and configured to discharge the process gases;
a heating member provided in the process chamber body;
a plasma power electrode member composed of electrodes arranged in the process chamber body at a distance from each other in a radial direction; and
a support plate member provided at a bottom inside the process chamber body.

2. The fluorination cleaning device according to claim 1, wherein the heating member is provided along an inner wall of the process chamber body, and the plasma power electrode member comprises a first plasma power electrode member provided in the process chamber body concentrically around a center of the process chamber body, and a second plasma power electrode member provided outside the first power electrode at a distance therefrom.

3. The fluorination cleaning device according to claim 1, further comprising, at a process gas inlet side, a diffusion member that allows the process gases introduced through the process gas inlet to diffuse.

4. The fluorination cleaning device according to claim 2, further comprising, at a process gas inlet side, a diffusion member that allows the process gases introduced through the process gas inlet to diffuse.

5. The fluorination cleaning device according to claim 1, wherein the process chamber body is configured such that a lower portion forming a bottom of the process chamber body is separated from an upper portion, and the fluorination cleaning device further comprises an up-and-down driving unit that drives the lower portion to be movable up and down.

6. The fluorination cleaning device according to claim 1, further comprising a rotational driving unit that rotatably drives the support plate member.

7. A fluorination cleaning apparatus for cleaning a liner-type part having an yttria (Y₂O₃) coating layer for a semiconductor dry etching system, comprising:
a plasma-heat treatment unit which is the fluorination cleaning device according to claim 1;
a process gas supply unit configured to supply a discharge gas, a non-fluorine reactive gas, and a reactive gas, which are process gases, to the plasma-heat treatment unit; and
a cleaning control unit configured to control a plasma heat treatment environment of the plasma-heat treatment unit and flow rates of the process gases that are supplied from the process gas supply unit.

8. A fluorination cleaning apparatus for cleaning a liner-type part having an yttria (Y₂O₃) coating layer for a semiconductor dry etching system, comprising:
a plasma-heat treatment unit which is the fluorination cleaning device according to claim 2;
a process gas supply unit configured to supply a discharge gas, a non-fluorine reactive gas, and a reactive gas, which are process gases, to the plasma-heat treatment unit; and
a cleaning control unit configured to control a plasma heat treatment environment of the plasma-heat treatment unit and flow rates of the process gases that are supplied from the process gas supply unit.

9. A fluorination cleaning apparatus for cleaning a liner-type part having an yttria (Y₂O₃) coating layer for a semiconductor dry etching system, comprising:
a plasma-heat treatment unit which is the fluorination cleaning device according to any claim 3;
a process gas supply unit configured to supply a discharge gas, a non-fluorine reactive gas, and a reactive gas, which are process gases, to the plasma-heat treatment unit; and
a cleaning control unit configured to control a plasma heat treatment environment of the plasma-heat treatment unit and flow rates of the process gases that are supplied from the process gas supply unit.

10. A fluorination cleaning apparatus for cleaning a liner-type part having an yttria (Y₂O₃) coating layer for a semiconductor dry etching system, comprising:
a plasma-heat treatment unit which is the fluorination cleaning device according to claim 4;
a process gas supply unit configured to supply a discharge gas, a non-fluorine reactive gas, and a reactive gas, which are process gases, to the plasma-heat treatment unit; and
a cleaning control unit configured to control a plasma heat treatment environment of the plasma-heat treatment unit and flow rates of the process gases that are supplied from the process gas supply unit.

11. A fluorination cleaning apparatus for cleaning a liner-type part having an yttria (Y₂O₃) coating layer for a semiconductor dry etching system, comprising:
a plasma-heat treatment unit which is the fluorination cleaning device according to claim 5;
a process gas supply unit configured to supply a discharge gas, a non-fluorine reactive gas, and a reactive gas, which are process gases, to the plasma-heat treatment unit; and
a cleaning control unit configured to control a plasma heat treatment environment of the plasma-heat treatment unit and flow rates of the process gases that are supplied from the process gas supply unit.

12. A fluorination cleaning apparatus for cleaning a liner-type part having an yttria (Y₂O₃) coating layer for a semiconductor dry etching system, comprising:
a plasma-heat treatment unit which is the fluorination cleaning device according to claim 6;
a process gas supply unit configured to supply a discharge gas, a non-fluorine reactive gas, and a reactive gas, which are process gases, to the plasma-heat treatment unit; and
a cleaning control unit configured to control a plasma heat treatment environment of the plasma-heat treatment unit and flow rates of the process gases that are supplied from the process gas supply unit.

13. The fluorination cleaning apparatus according to claim 7, wherein the cleaning control unit is configured to control a combination of a plurality of process parameters among process parameters, including process gas introductions, plasma generation power, treatment time, heat treatment temperature, treatment space pressure, and the number of treatment cycles.

14. The fluorination cleaning apparatus according to claim 8, wherein the cleaning control unit is configured to control a combination of a plurality of process parameters among process parameters, including process gas introductions, plasma generation power, treatment time, heat treatment temperature, treatment space pressure, and the number of treatment cycles.

15. The fluorination cleaning apparatus according to claim 9, wherein the cleaning control unit is configured to control a combination of a plurality of process parameters among process parameters, including process gas introductions, plasma generation power, treatment time, heat treatment temperature, treatment space pressure, and the number of treatment cycles.

16. The fluorination cleaning apparatus according to claim 10, wherein the cleaning control unit is configured to control a combination of a plurality of process parameters among process parameters, including process gas introductions, plasma generation power, treatment time, heat treatment temperature, treatment space pressure, and the number of treatment cycles.

17. The fluorination cleaning apparatus according to claim 11, wherein the cleaning control unit is configured to control a combination of a plurality of process parameters among process parameters, including process gas introductions, plasma generation power, treatment time, heat treatment temperature, treatment space pressure, and the number of treatment cycles.

18. The fluorination cleaning apparatus according to claim 12, wherein the cleaning control unit is configured to control a combination of a plurality of process parameters among process parameters, including process gas introductions, plasma generation power, treatment time, heat treatment temperature, treatment space pressure, and the number of treatment cycles.
